(19) United States
(12) Patent Application Publication
(10) Pub. No.: US 2026/0033030 A1
(43) Pub. Date: Jan. 29, 2026

(54) FORKED DEEP TRENCH ISOLATION STRUCTURE FOR IMAGE SENSOR AND METHODS THEREOF

(71) Applicant: OMNIVISION TECHNOLOGIES, INC., Santa Clara, CA (US)

(72) Inventor: Shiyu Sun, Cupertino, CA (US)

(21) Appl. No.: 18/787,303

(22) Filed: Jul. 29, 2024

(51) Int. Cl. H01L 27/146

(52) U.S. Cl. CPC H10F 39/807; H10F 39/014; H10F 39/18

(57) ABSTRACT

An image sensor comprising a photodiode and a forked deep trench isolation (DTI) structure is described. The photodiode is disposed within a semiconductor substrate having a first side and a second side opposite the first side. The forked DTI structure is configured to isolate the photodiode from adjacent photodiodes included in the image sensor. The forked DTI structure includes a trench disposed within the semiconductor substrate between the first side and the second side, a forked structure disposed within the trench and including a first prong, a second prong, and an intermediary portion to form a first cavity within the trench, and a second cavity disposed within the trench. The first cavity includes a first material and the second cavity includes a second fill material.

### TECHNICAL FIELD

This disclosure relates generally to image sensors, and in particular but not exclusively, relates to CMOS image sensors and applications thereof.

### BACKGROUND INFORMATION

Image sensors are one type of semiconductor device that have become ubiquitous and are now widely used in digital cameras, cellular phones, security cameras, as well as, medical, automobile, and other applications. As image sensors are integrated into a broader range of electronic devices it is desirable to enhance their functionality, performance metrics, and the like in as many ways as possible (e.g., resolution, power consumption, dynamic range, size, etc.) through both device architecture design as well as image acquisition processing. However, it is appreciated that many of these metrics are inversely related. For example, pixel size may be increased to improve dynamic range but have increased noise. In another example, resolution may be increased by increasing the number of pixels, but if pixel size is maintained then the physical size of the image sensor increases. Accordingly, improving one or more performance metrics of semiconductor devices such as image sensors while mitigating adverse effects on other performance metrics remains challenging.

The typical image sensor operates in response to image light reflected from an external scene being incident upon the image sensor. The image sensor includes an array of pixels having photosensitive elements (e.g., photodiodes) that absorb a portion of the incident image light and generate image charge upon absorption of the image light. The image charge photogenerated by the pixels may be measured as analog output image signals on column bit lines that vary as a function of the incident image light. In other words, the amount of image charge generated is proportional to the intensity of the image light, which is readout as analog image signals from the column bit lines and converted to digital values to produce digital images (i.e., image data) representative of the external scene.

### BRIEF DESCRIPTION OF THE DRAWINGS

Non-limiting and non-exhaustive embodiments of the invention are described with reference to the following figures, wherein like reference numerals refer to like parts throughout the various views unless otherwise specified. Not all instances of an element are necessarily labeled so as not to clutter the drawings where appropriate. The drawings are not necessarily to scale, emphasis instead being placed upon illustrating the principles being described.

FIG. 1A illustrates an image sensor with a forked deep trench isolation structure, in accordance with an embodiment of the disclosure.

FIG. 1B illustrates a plan view of the image sensor of FIG. 1A, in accordance with an embodiment of the disclosure.

FIG. 1C illustrates a cross-sectional view along line X-X′ of the image sensor of FIG. 1B, in accordance with an embodiment of the disclosure.

FIG. 1D illustrates a magnified cross-sectional view of a pixel isolated by a forked deep trench isolation structure included in the image sensor of FIG. 1B, in accordance with an embodiment of the disclosure.

FIG. 2 illustrates the forked deep trench isolation structure of FIG. 1D modified to include an expanded isolation structure, in accordance with an embodiment of the disclosure.

FIG. 3A-3R illustrate a method for fabricating an image sensor with a forked deep trench isolation structure, in accordance with an embodiment of the disclosure

FIG. 4 is a functional block diagram of an imaging system including an image sensor with a forked deep trench isolation structure, in accordance with an embodiment of the disclosure.

### DETAILED DESCRIPTION

Embodiments of an apparatus, system, and method each related to an image sensor with a forked deep trench isolation structure are described herein. In the following description, numerous specific details are set forth to provide a thorough understanding of the embodiments. One skilled in the relevant art will recognize, however, that the techniques described herein can be practiced without one or more of the specific details, or with other methods, components, materials, etc. In other instances, well-known structures, materials, or operations are not shown or described in detail to avoid obscuring certain aspects.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

It will be understood that, although the terms first, second, third, etc., may be used in the disclosure and claims to describe various elements, these elements should not be limited by these terms and should not be used to determine the process sequence or formation order of associated elements. Unless indicated otherwise, these terms are merely used to distinguish one element from another element. Thus, a first element discussed below could be termed a second element without departing from the teachings of the disclosed embodiments.

Throughout this specification, several terms of art are used. These terms are to take on their ordinary meaning in the art from which they come, unless specifically defined herein or the context of their use would clearly suggest otherwise. It should be noted that element names and symbols may be used interchangeably through this document (e.g., Si vs. silicon); however, both have identical meaning.

Described herein are embodiments of an image sensor with a forked deep trench isolation (DTI) structure configured to isolate photodiodes included in the image sensor and corresponding method of fabrication. In some embodiments, the structure and fabrication process of the forked DTI structure allows for both a high-K material to provide surface passivation while maintaining compatibility with high-temperature processing steps to anneal out defects. In the same or other embodiments, the forked DTI structure is configured such that the surface (e.g., front side or backside of the semiconductor substrate the forked DTI structure is formed therein) or the interface between the DTI structure and the semiconductor substrate is protected during subsequent processing steps. Additional benefits of the forked DTI structure described in embodiments of the disclosure is a relaxed self-aligned process to increase yield and reduction in fabrication complexity and cost.

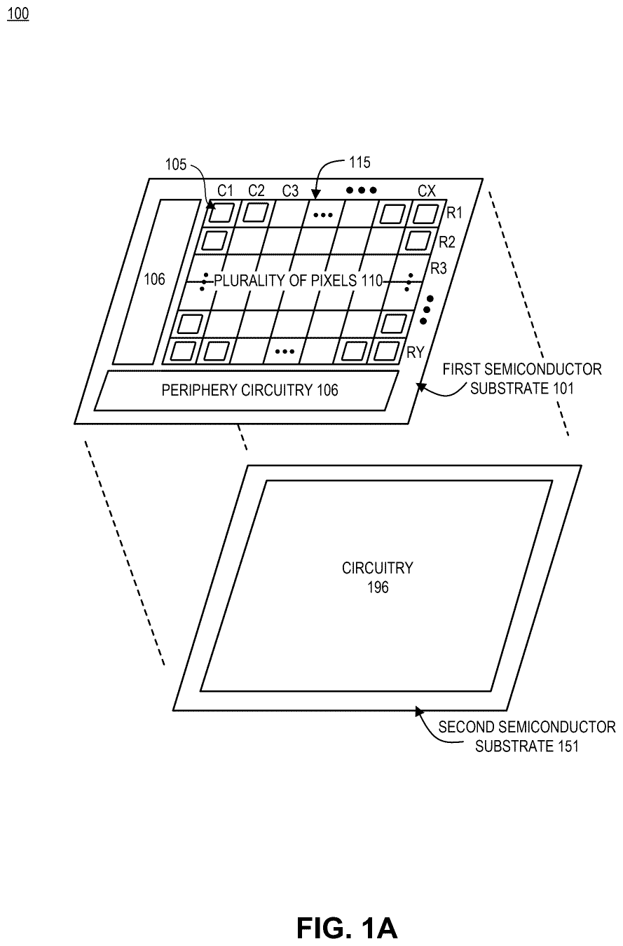

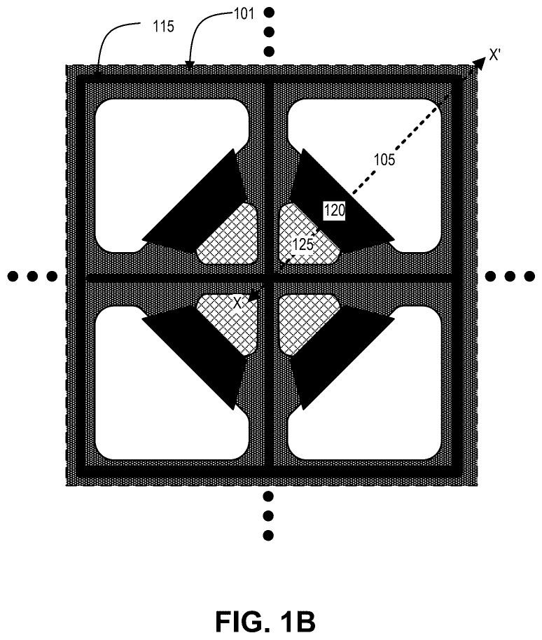

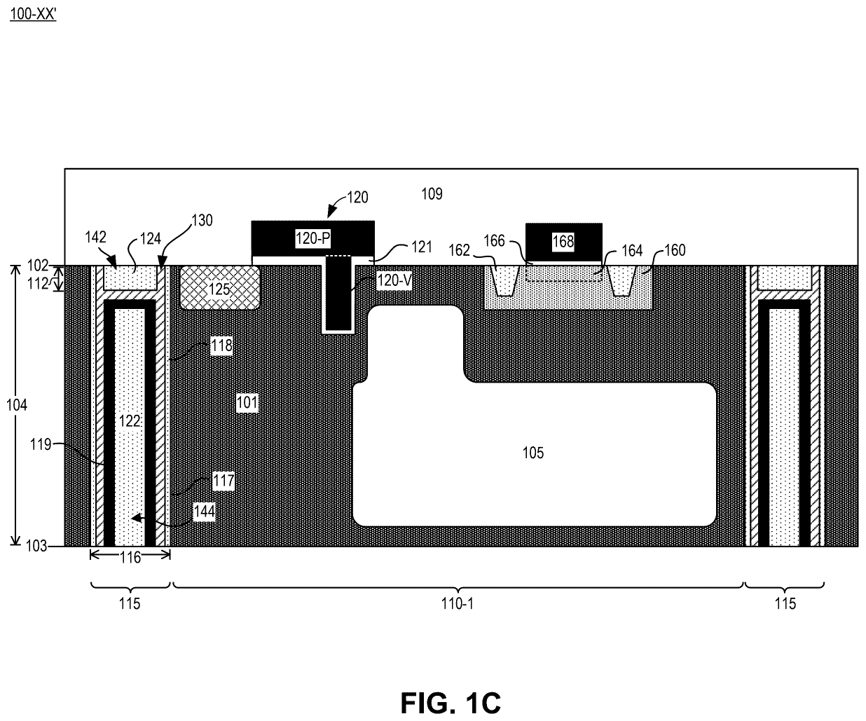

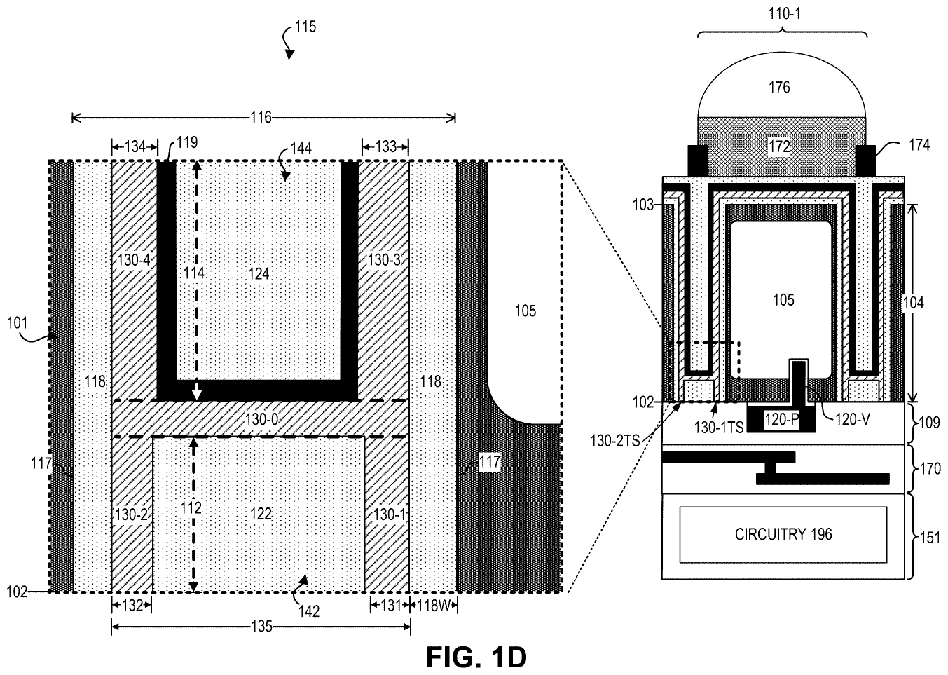

FIG. 1A illustrates an image sensor 100 with a forked deep trench isolation (DTI) structure 115, in accordance with an embodiment of the disclosure. Image sensor 100 is a stacked complementary metal-oxide-semiconductor (CMOS) device that includes a first semiconductor substrate 101 and a second semiconductor substrate 151 that are stacked vertically and electrically coupled together. It is appreciated that stacked image sensor 100 may include more than two stacked semiconductor substrates and is not limited to first semiconductor substrate 101 and second semiconductor substrate 151. First semiconductor substrate 101 includes periphery circuitry 106, a plurality of pixels 110, and forked DTI structure 115. Plurality of pixel 110 are arranged in rows (e.g., R1, R2, R3, . . . , RY) and columns (e.g., C1, C2, C3, . . . , CX) to form a pixel array. Each pixel included in plurality of pixels 110 includes a photodiode (e.g., a pixel positioned in row “R1” and column “C1” of the pixel array includes photodiode 105). Forked DTI structure 115 provides isolation (e.g., physical, electrical, and/or optical) for individual pixels included in plurality of pixels 110. For example, forked DTI structure 115 isolates photodiode 105 from adjacent photodiodes (e.g., photodiodes associated with pixels positioned in row “R1” and column “C2,” row “R2” and column “C1,” and row “R2” and column “C2”) in order to mitigate crosstalk (e.g., electrical and/or optical) therebetween. In some embodiments, groups of adjacent pixels may be referred to as a pixel cell if they share a common color filter and/or readout circuitry (see, e.g., FIG. 1B).

It is appreciated that the term “semiconductor substrate” recited throughout the disclosure may correspond to a part of or an entirety of a semiconductor wafer (e.g., a silicon wafer). In some embodiments, the semiconductor substrate (e.g., first semiconductor substrate 101 and/or second semiconductor substrate 151) includes or is otherwise formed of silicon, a silicon germanium alloy, germanium, a silicon carbide alloy, an indium gallium arsenide alloy, any other alloys formed of III-V group compounds, combinations thereof, one or more epitaxial layers of the aforementioned materials, or a bulk substrate thereof. More specifically, first semiconductor substrate 101 and/or second semiconductor substrate 151 may correspond to any semiconductor material or combination of materials that may be doped or otherwise configured to facilitate the formation of an integrated circuit (e.g., forming individual circuitry components such as source/drain regions of transistors, memory elements, photodiodes, or the like). For example, first semiconductor substrate 101 may correspond to one or more epitaxial layers (e.g., P or N doped silicon) formed on a carrier wafer. In such an embodiment, photodiode 105 and/or other photodiodes included in plurality of pixels 110 may be formed in the one or more epitaxial layers corresponding to first semiconductor substrate 101 while the carrier wafer may be removed or otherwise thinned during fabrication. The first semiconductor substrate 101 may subsequently be stacked and interconnected with second semiconductor substrate 151. In some embodiments, first semiconductor substrate 101 and/or second semiconductor substrate 151 may be formed of the same or different materials. It is appreciated that the term “photodiode” (e.g., photodiode 105 and/or other photodiodes included in plurality of pixels 110) correspond to a doped region disposed within first semiconductor substrate 101 configured to photogenerate image charge in response to incident light. For example, photodiode 105 may correspond to an n-doped region disposed within a p-type semiconductor substrate or an n-doped region surrounded by a p-type well disposed within first semiconductor substrate 101.

Periphery circuitry 106 included in or on first semiconductor substrate 101 and circuitry 196 included in or on second semiconductor substrate 151 facilitate or otherwise support operation of image sensor 100. In some embodiments, support circuitry that may be included in periphery circuitry 106 and/or circuitry 196 may include, but is not limited to, row and column decoders and drivers, analog signal processing chains, digital imaging processing blocks, memory, timing and control circuits, input/output interfaces, a vertical scanner, sample and hold circuitry, amplifiers, analog-to-digital converter circuitry, signal processing circuitry, and any other embodiments of logic and/or circuitry that is appropriate for the function of image sensor 100. In the same or other embodiments, circuitry 196 may correspond to or otherwise include an application specific integrated circuit or a general-purpose microprocessor, or the like. It is further appreciated that readout circuitry (e.g., transfer transistor, row select transistor, source-follower transistor, low conversion gain transistor, dual floating diffusion transistor, reset transistor, lateral overflow integration capacitor, floating diffusion, other memory elements or transistors to facilitate readout or operation of image sensor 100) may be included in plurality of pixels 110, periphery circuitry 106, and/or circuitry 196. For example, in some embodiments, certain elements that facilitate readout of image generate generated by photodiodes (e.g., photodiode 105) included in plurality of pixels 110 may be offloaded to second semiconductor substrate 151 to enable increased photodiode fill factor and/or more efficient space utilization.

It is appreciated that the view presented in FIG. 1A may omit certain elements of image sensor 100 to avoid obscuring details of the disclosure. In other words, not all elements of image sensor 100 may be labeled, illustrated, or otherwise shown within FIG. 1A or other figures throughout the disclosure. It is further appreciated that in some embodiments, image sensor 100 may not necessarily include all elements shown. For example, in some embodiments, image sensor 100 may not be a stacked CMOS device. Additionally, it is appreciated that embodiments of the disclosure generally related to forked DTI structure 115 configured to provide physical, electrical, and/or optical isolation for plurality of pixels 110. However, it is appreciated that the benefits of forked DTI structure 115 may be applicable to devices other than image sensors and thus forked DTI structure 115 or other forked DTI structures and corresponding methods described in embodiments of the disclosure should not be deemed limited to image sensors.

FIG. 1B illustrates a plan view of image sensor 100 of FIG. 1A, in accordance with an embodiment of the disclosure. FIG. 1B may be a plan or top view from a side of image sensor 100 having transfer gates formed thereon (e.g., a front side). More specifically, the illustrated view shows an example pixel cell formed by a two-by-two group of pixels included in plurality of pixel 110, with individual pixels included in the pixel cell isolated by forked DTI structure 115. As illustrated, each pixel of the pixel cell includes respective instances of photodiode 105, a transfer gate 120, and a floating diffusion 125. Transfer gate 120 is configured to facilitate transfer of photogenerated image charge from photodiode 105 to floating diffusion 125. It is appreciated that in some embodiments, multiple instances of the two-by-two group of pixels that form the illustrated pixel cell may be repeated to form a pixel cell array to facilitate imaging an external scene with image sensor 100. In some embodiments, components may be shared within a given pixel cell (e.g., floating diffusion 125 of each pixel in the illustrated pixel cell may be selectively coupled together, for example, through metal wiring). In the same or another embodiment, each pixel included in the illustrated pixel cell may have a common color filter (e.g., each pixel of the pixel cell may correspond to the same color pixel such as red, green, blue, white, infrared, or the like) such that groups of pixel cells may collectively form a full color image pixel (e.g., two green pixel cells, one blue pixel cell, and one red pixel cell). However, it should be appreciated that the illustrated configuration of pixels and/or pixel cells and corresponding layout is just one example that forked DTI structure 115 may be used to provide pixel isolation and should not be deemed limiting. Indeed, forked DTI structure 115 extends laterally around individually pixels (e.g., to surround and/or isolate components of a given pixel disposed within first semiconductor substrate 101) cell and thus is generally compatible with a wide variety of pixel and/or pixel cell layouts, in accordance with embodiments of the disclosure.

FIG. 1C illustrates a cross-sectional view 100-XX′ along line X-X′ of image sensor 100 of FIG. 1B, in accordance with an embodiment of the disclosure. The cross-sectional view 100-XX′ is representative of a cross-section for pixel 110-1 included in plurality of pixels 110 of FIG. 1A that is laterally surrounded by and isolated from adjacent pixels included in plurality of pixels 110 by forked DTI structure 115. It is appreciated that each other pixel included in plurality of pixel 110 may similarly be represented by the view illustrated in FIG. 1C. The illustrated view shows pixel 110-1 laterally surrounded by forked DTI structure 115. Pixel 110-1 includes photodiode 105, transfer gate 120 having planar portion 120-P on first side 102 of first semiconductor substrate 101 and vertical portion 120-V, gate dielectric 121, floating diffusion 125, isolation well 160, shallow trench isolation (STI) structure 162, source/drain region 164, gate dielectric 166, and gate electrode 168. DTI structure 115 includes trench 116 extending from first side 102 to second side 103 of first semiconductor substrate 101, liner material 118, anti-reflective (AR) material layer 119, forked structure 130, first cavity 142 including first fill material 122, and second cavity 144 including second fill material 124. The illustrated view also shows an interlayer dielectric 109 coupled to first side 102 of first semiconductor substrate 101.

In the illustrated embodiment, photodiode 105, floating diffusion 125, and/or source/drain region 164 include or otherwise correspond to a doped region having a different or opposite conductivity type relative to the conductive type of first semiconductor 101 or the surrounding medium the components are disposed therein (e.g., n-doped regions disposed within or surrounded by a p-doped semiconductor material or substrate). It is appreciated that the L-shaped form of photodiode 105 is mere an illustration and the exact shape of photodiode 105 may depend on specific doping profile design and implantation scheme (e.g., implant dosage, implant energy, annealing process parameters, etc.). Isolation well 160 corresponds to a doped region having an opposite or different conductivity type relative to source/drain region 164 (e.g., isolation well 160 may correspond to a p+ doped region having a greater dopant concentration relative to first semiconductor substrate 101 when source/drain region 164 corresponds to an n-type doped region). In the same or other embodiments, transfer gate 120 includes planar portion 120-P and vertical portion 120-V disposed proximate to the photodiode 105. The transfer gate 120 and gate electrode 168 may include or otherwise correspond to a metal material (e.g., Au, Ag, Al, Cu, Ta, Ti, Nb, W, Mo), polycrystalline silicon (extrinsic or intrinsic), a silicide material, metal composites (e.g., WN, TiN, TaN, TiAl, TiAlC, other metal nitrides, RuOₓ, or other metal oxide electrode materials), other conductive materials with the appropriate conductivity and work function, or combinations thereof. In some embodiments, gate dielectric 121 and/or gate dielectric 166 include one or more insulating materials (e.g., silicon dioxide, silicon oxynitride, hafnium dioxide, alumina oxide, zirconium oxide, or other gate dielectric materials known by one of ordinary skill in the art). In the same or other embodiments, interlayer dielectric 109 includes one or more dielectric or insulating materials such as silicon dioxide, boronsilicate glass (BSG), borophosphosilicate glass (BPSG), organosilicate glass such as SiCOH, porous SiCOH, other insulating materials, or combinations thereof. In the same or other embodiments, liner material 118, first fill material 122, second fill material 124, and/or STI structure 162 include an insulating material (e.g., silicon dioxide or other metal oxide material). In the same or other embodiment, first fill material 122 and/or second fill material 125 includes polycrystalline silicon (polysilicon). In the same or other embodiments, forked structure 130 includes a high-K material (e.g., material with a dielectric constant greater than silicon dioxide such as HfOₓ, HfSiO, HfSiON, AlOₓ, or the like). In the same or other embodiments, AR material layer 119 includes silicon nitride, a high-k material such as tantalum pentoxide, Ta₂O₅, hafnium dioxide, HfO₂, or combinations thereof.

In one embodiment, the first fill material 122 and the second fill material 124 have a same composition. In other embodiments, the first fill material 122 and the second fill material 124 have a different composition (e.g., the first fill material 122 is different from the second fill material 124). In some embodiments, a composition of the first fill material 122 and/or the second fill material 124 is different from a composition of the forked structure 130. In some embodiments, liner material 118 is disposed between sidewalls 117 of trench 116 and second fill material 124. In the same or other embodiments, liner material 118 is disposed between sidewalls 117 of trench 116 and first fill material 122.

As illustrated in FIG. 1C, vertical portion 120-V of transfer gate 120 extends vertically (i.e., depthwise) from first side 102 of first semiconductor substrate 101 into first semiconductor substrate 101 while planar portion 120-P of transfer gate 120 extends laterally (e.g., planar to first side 102) within interlayer dielectric 109. In the same or other embodiments, vertical portion 120-V is configured to extend from planar portion 120-P the first semiconductor substrate 101. Transfer gate 120 is isolated from components disposed within first semiconductor substrate 101 by gate dielectric 121 to form a transfer transistor that includes photodiode 105 and floating diffusion 125 (e.g., such that photogenerated image charge may be transferred from photodiode 105 to floating diffusion 125 in response to a transfer signal applied to transfer gate 120). Source/drain region 164, disposed within first semiconductor substrate 101, in combination with gate dielectric 166 and gate electrode 168 forms a transistor that may correspond to or otherwise be included in readout circuitry for image sensor 100 (e.g., the transistor may correspond to a source-follower transistor, a row select transistor, a reset transistor, a low conversion gain transistor, a dual floating diffusion transistor, or other transistor configured to facilitate operation of image sensor 100). As illustrated, source/drain region 164 may be disposed within first semiconductor substrate 101 between first side 102 of first semiconductor substrate 101 and photodiode 105.

In the illustrated embodiment, forked DTI structure 115 is a full DTI structure extending a full depth 104 of first semiconductor substrate 101. In other words, forked DTI structure 115 extends entirely through first semiconductor substrate 101 to provide improved isolation for plurality of pixels 110. In some embodiments, forked DTI structure 115 may define a pixel region for each individual pixel included in plurality of pixels 110. For example, forked DTI structure 115 may be configured to form a grid structure that extends into semiconductor substrate 101 and laterally surrounds each individual pixel. In the same or other embodiments, liner material 118 and forked structure 130 (e.g., structure within trench 116 having a diagonal slash-line fill) extend entirely or completely through first semiconductor substrate 101 (e.g., trench 116, liner material 118, and forked structure 130 extend from first side 102 to second side 103). In the same embodiment, first cavity 142, second cavity 144, and AR material layer 119 do not individually extend entirely through first semiconductor substrate 101. In the illustrated embodiment, liner material 118 lines sidewalls 117 of trench 116 while forked structure 130 conformally coats or is otherwise disposed proximate to liner material 130. In some embodiments, liner material 118 and forked structure 130 each extend entirely through first semiconductor substrate 101 such that liner material 118 and forked structure 130 extend continuously from first side 102 to second side 103 of first semiconductor substrate 101. First cavity 142 is disposed or defined within trench 116 and extends into first semiconductor substrate 101 from first side 102 to a depth 112 into first semiconductor substrate 101. Second cavity 144 extends into first semiconductor substrate 101 from second side 103.

As illustrated in FIG. 1C, floating diffusion 125 is disposed between forked structure 130 and vertical portion 120-V of transfer gate 120. More specifically, forked structure 130 includes first and second prongs (see, e.g., FIG. 1D) that have first cavity 142 disposed therebetween. In the same or other embodiment, a first prong (e.g., an inner prong disclosed closer to floating diffusion 125 relative to an outer prong) of forked structure 130 is disposed between floating diffusion 125 and first cavity 142. In the same or another embodiment, the first prong of forked structure 130 is disposed between vertical portion 120-V of transfer gate 120 and first cavity 142. In the same or another embodiment, STI structure 162 is disposed between source/drain region 164 and forked structure 130. In some embodiments, vertical portion 120-V extends deeper into first semiconductor substrate 101 from first side 102 relative to a depth the first prong, the second prong, and/or the intermediary portion (e.g., first prong 130-1, second prong 130-2, and/or intermediary portion 130-0 illustrated in FIG. 1D) extend into first semiconductor substrate 101 relative to first side 102. In other words, in some embodiments, vertical portion 120-V is disposed closer to second side 103 of first semiconductor substrate 101 than the first prong, the second prong, and/or the intermediary portion of forked structure 130. For example, a distal end of vertical portion 120-V is disposed closer to second side 103 of first semiconductor substrate 101 than the intermediary portion of the forked structure 130. In another example, a first separation distance between the vertical portion 120-V and second side 103 of first semiconductor substrate 101 is less than a second separation distance between the intermediary portion, the first prong, and/or the second portion of the forked structure 130 and the second side 103 of the first semiconductor substrate.

FIG. 1D illustrates a magnified cross-sectional view of pixel 110-1 isolated by forked DTI structure included 115 included in the image sensor 100 of FIG. 1B, in accordance with an embodiment of the disclosure. It is appreciated that pixel 110-1 illustrated in FIG. 1D also shows metallization layer 170 (e.g., one or more metal wires or vias to provide signal routing) coupled between second semiconductor substrate 151 and interlayer dielectric 109. Pixel 110-1 further includes color filter 172 (e.g., a red, green, blue, white, infrared, or other color filter), a metal grid 174, and a microlens 176 to direct and filter incident light towards photodiode 105.

Forked DTI structure 115 is configured to isolate photodiode 105 from adjacent photodiodes included in image sensor 100 within the first semiconductor substrate 101. Forked DTI structure 115 includes trench 116 disposed within first semiconductor substrate 101 between first side 102 and second side 103. In some embodiments, forked structure 130 is disposed within trench 116 and includes intermediary portion 130-0, first prong 130-1, second prong 130-2, third prong 130-3, and fourth prong 130-4. First prong 130-1 and second prong 130-2, third prong 130-3, and fourth prong 130-4 each extend from intermediary portion 130-0, which may form a monolithic structure (e.g., first prong 130-1, second prong 130-2, third prong 130-3, and fourth prong 130-4 are each directly coupled to intermediary portion 130-0). In the same or other embodiments, first prong 130-1 and second prong 130-2 each extend from intermediary portion 130-0 towards first side 102 of first semiconductor substrate 101 to form or define first cavity 142 within trench 116 while third prong 130-3 and fourth prong 130-4 each extend from intermediary portion 130-0 towards second side 103 of first semiconductor substrate 101 to form or define second cavity 144 within trench 116. In the illustrated embodiment, first cavity 142 is disposed between first prong 130-1 and second prong 130-2 while second cavity 144 is disposed between third prong 130-3 and fourth prong 130-4. As illustrated, intermediary portion 130-0 is disposed between first cavity 142 and second cavity 144 with first cavity 142 including first fill material 122 and second cavity 144 including second fill material 124. As illustrated, intermediary portion 130-0 separates first cavity 142 from second cavity 144. As illustrated, second cavity 144 also includes AR material layer 119, which may conformally coat (i.e., line) intermediary portion 130-0, third prong 130-3, and fourth prong 130-4 of forked structure 130.

First prong 130-1, second prong 130-2, third prong 130-3, and fourth prong 130-4 each extend vertically into first semiconductor substrate 101 (e.g., depthwise of first semiconductor substrate 101 such that a longitudinal direction of first prong 130-1, second prong 130-2, third prong 130-3, and fourth prong 130-4 extends from first side 102 to second side 130) while intermediary portion 130-0 extends laterally (e.g., planar to first side 102 or second side 103) through first semiconductor substrate 101. In some embodiments, first prong 130-1, second prong 130-2, third prong 130-3, and fourth prong 130-4 extend perpendicular to intermediary portion 130-0. In the same or other embodiments, first prong 130-1 is aligned with third prong 130-3 and second prong 130-2 is aligned with fourth prong 130-4 (e.g., to respectively line or otherwise conformally coat liner material 118). In some embodiments, forked structure 130 is corresponds to a double-sided forked structure or may otherwise be described as an “H” shape with laterally adjacent prongs (e.g., first prong 130-1 and second prong 130-2 or third prong 130-3 and fourth prong 130-4) respectively defining first cavity 142 and second cavity 144. In the illustrated embodiment, intermediary portion 130-0 extends continuously from adjacent prongs (e.g., such that intermediary portion 130-0 couples first prong 130-1 to second prong 130-1 and further couples third prong 130-3 to fourth prong 130-4 such that first cavity 142 is separated from second cavity 144).

In the illustrated embodiment, forked DTI structure 115 includes liner material 118 disposed between sidewalls 117 of trench 116 and first cavity 142. Liner material 118 is further disposed between sidewalls 117 of trench 116 and second cavity 144. Liner material 118 is disposed between material of first semiconductor substrate 101 and forked structure 130. In the same or a different embodiment, liner material 118 and forked structure 130 are disposed between first cavity 142 and material of first semiconductor substrate 101. In the same or a different embodiment, liner material 118 and forked structure 130 are disposed between second cavity 144 and material of first semiconductor substrate 101. In some embodiments, liner material 118 may form a thin liner layer having a thickness ranging between 1 nm to 3 nm. In the same or a different embodiment, first cavity 142 may be vertically aligned with second cavity 144. In some embodiments, first prong 130-1 is disposed between liner material 118 and first cavity 142, second prong 130-2 is disposed between liner material 118 and first cavity 142, third prong 130-3 is disposed between liner material 118 and second cavity 144, and fourth prong 130-4 is disposed between liner material 118 and second cavity 144. In the same or other embodiments, first prong 130-1 is disposed between liner material 118 and first fill material 122, second prong 130-2 is disposed between liner material 118 and first fill material 122, third prong 130-3 is disposed between liner material 118 and second fill material 124, and fourth prong 130-4 is disposed between liner material 118 and second fill material 124. In some embodiments, AR material layer 119 is disposed between second fill material 124 and third prong 130-3, AR material layer 119 is also disposed between second fill material 124 and fourth prong 130-4, and AR material layer 119 is disposed between second fill material 124 and intermediary portion 130-0. In some embodiments, AR material layer 119 and intermediary portion 130-0 collectively separate first fill material 122 and second fill material 124. In the same or other embodiments, the intermediary portion 130-0 laterally extends continuously from the first prong 130-1 to the second prong 130-2 such that the first fill material 122 is separated from the second fill material 124.

In some embodiments, first cavity 142 extends a first depth 112 into first semiconductor substrate 101 from first side 102 while second cavity 144 extends a second depth 114 into first semiconductor substrate 101 from second side 103. In some embodiments, first depth 112 is less than second depth 114. In other words, second cavity 144 extends deeper into first semiconductor substrate 101 relative to first cavity 142. In the same or other embodiments, first prong 130-1 and second prong 130-2 each extend first depth 112 into first semiconductor substrate 101 from first side 102 defining first cavity 142 and third prong 130-3 and fourth prong 130-4 each extend second depth 114 into first semiconductor substrate 101 from second side 103 defining second cavity 144. In some embodiments, first prong 130-1 and second prong 130-2 extend a same depth into first semiconductor substrate 101 (e.g., first depth 112). In the same or other embodiments, third prong 130-3 and fourth prong 130-4 extend a same depth into first semiconductor substrate 101 (e.g., second depth 114). In other words, a depth of first prong 130-1 and second prong 130-2 is different from third prong 130-3 and fourth prong 130-4. In some embodiments, intermediary portion 130-0 is disposed closer to first side 102 of first semiconductor substrate 101 relative to second side 103 such that third prong 130-3 and forth prong 130-4 are longer than first prong 130-1 and second prong 130-2 in the depthwise direction (e.g., along a direction perpendicular to first side 102 of first semiconductor substrate 101). In the illustrated embodiment, first depth 112 is less than second depth 114 such that third prong 130-3 is longer than first prong 130-1 and fourth prong 130-4 is longer than second prong 130-2 in the depthwise direction. In some embodiments, forked structure 130 extends the full depth 104 of first semiconductor substrate 101. In the same or other embodiments, first prong 130-1, intermediary portion 130-0, and third prong 130-3 collectively extend the full depth 104 of first semiconductor substrate 101 such that a top surface 130-1TS may be substantially level with first side 102 of the first semiconductor substrate 101 and part of third prong 130-3 extends to or through second side 103 of first semiconductor substrate 101. In the same or other embodiments, second prong 130-2, intermediary portion 130-0, and fourth prong 130-4 collectively extend the full depth 104 of first semiconductor substrate 101 such that a top surface 130-2TS may be substantially level with first side 102 of first semiconductor substrate 101 and part of fourth prong 130-4 extends to or through second side 103 of the first semiconductor substrate 101. As such, forked structure 130 extends from first side 102 to second side 103 of first semiconductor substrate 101 and is disposed proximate to material (e.g., a boundary of trench 116) of first semiconductor substrate 101 to provide passivation. More specifically, in some embodiments, forked structure 130 includes a high-K material that creates a hole accumulated region proximate to the interface boundary between trench 116 and first semiconductor substrate 101 that provides passivation of charge traps formed at the interface boundary (e.g., due to damage from etching first semiconductor substrate 101 to form trench 116) that results in reduced dark current.

In some embodiments, first prong 130-1 extends a first width 131, second prong 130-2 extends a second width 132, third prong 130-3 extends a third width 133, fourth prong 130-4 extends a fourth width 134, and intermediary portion 130-0 extends a fifth width 135. In some embodiments, first width 131 of first prong 130-1 proximate to first side 102 of first semiconductor substrate 101 is less than third width 133 of third prong 130-3 proximate to second side 103 of first semiconductor substrate 101 along a direction parallel to a surface (e.g., first side 102 or second side 103) of first semiconductor substrate 101. In the same or other embodiments, second width 132 of second prong 130-2 proximate to first side 102 of first semiconductor substrate 101 is less than fourth width 134 of fourth prong 130-4 proximate to second side 103 of first semiconductor substrate 101 along a direction parallel to a surface (e.g., first side 102 or second side 103) of first semiconductor substrate 101. In one embodiment, each of first width 131 and second width 132 may range from 4 nm to 6 nm. In the same or another embodiment, each of third width 133 and fourth width 134 may range from 6.5 nm to 8 nm. In some embodiments, first width 131 of first prong 130-1, second width 132 of second prong 130-2, third width 133 of third prong 130-3, and fourth width 134 of fourth prong 130-4 are each less than fifth width 135 of intermediary portion 130-0. In other words, intermediary portion 130-0 is wider or thicker than first prong 130-1, second prong 130-2, third prong 130-3, and fourth prong 130-4. In some embodiments, the fifth width 135 may be defined by a thickness 118W of liner material 118 (e.g., a width of trench 116 minus twice thickness 118W corresponds to fifth width 135).

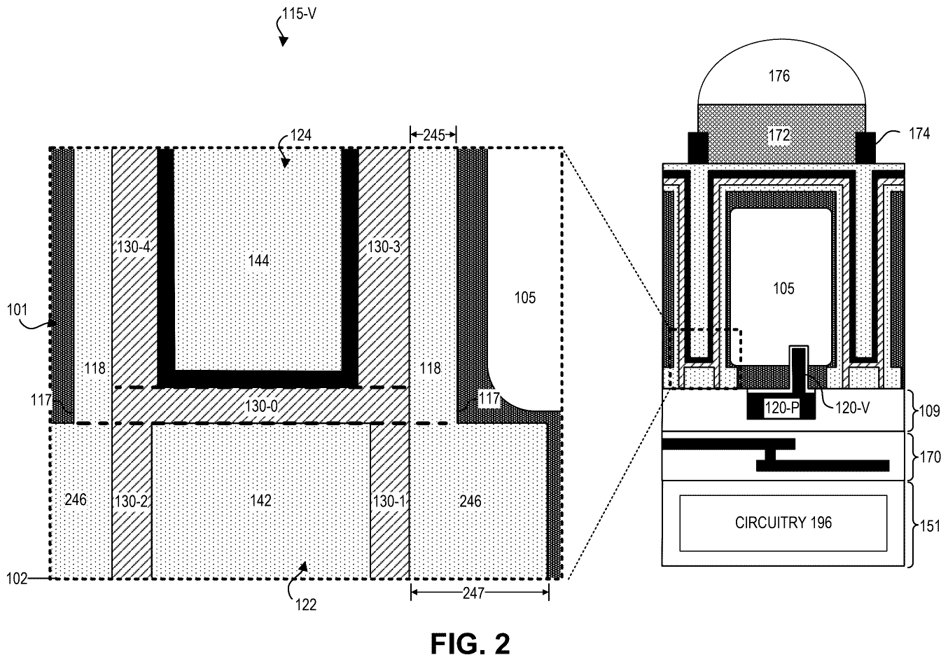

FIG. 2 illustrates the forked deep trench isolation structure 115 of FIG. 1D modified to include an expanded isolation structure 246, in accordance with an embodiment of the disclosure. In some embodiments, the modified forked DTI structure may be referred to as forked DTI structure 115-V. Expanded isolation structure 246 provides additional isolation to adjacent elements (e.g., floating diffusion, photodiode, or the like) and/or mitigates overetching during subsequent processing steps in combination with first fill material 122 to prevent damage proximate to first side 102 of first semiconductor substrate 101. It is appreciated that inclusion of expanded isolation structure 246 may further increase manufacturing cost relative to the illustrated embodiment of FIG. 1A-1D as an additional photomask may be necessary during fabrication.

Referring back to FIG. 2, extended isolation structure 246 may have a same composition as first fill material 122 and/or liner material 118. Extended isolation structure 246 extends from first side 102 of first semiconductor substrate 101 towards a portion of liner material 118 disposed proximate to third prong 130-3. Extended isolation structure 246 further extends from first side 102 of first semiconductor substrate 101 towards a portion of liner material 118 disposed proximate to fourth prong 130-4. In some embodiments, a first thickness 245 of liner material 118 proximate to third prong 130-3 is less than a second thickness 247 of extended isolation structure 246. In other words, extended isolations structure 246 is wider or thicker than liner material 118. In the illustrated embodiment, first prong 130-1 is disposed between extended isolation structure 246 and first fill material 122. In the same or other embodiment, second prong 130-2 is disposed between extended isolation structure 246 and first fill material 122. In some embodiments, extended isolation structure 246 and first fill material 122 and/or second fill material 124 have a same composition.

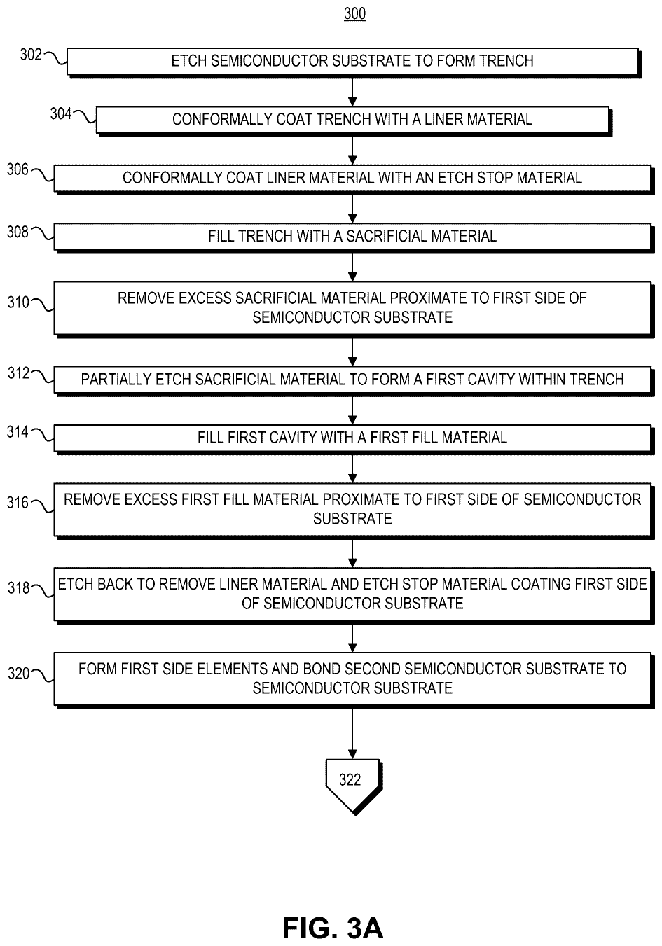

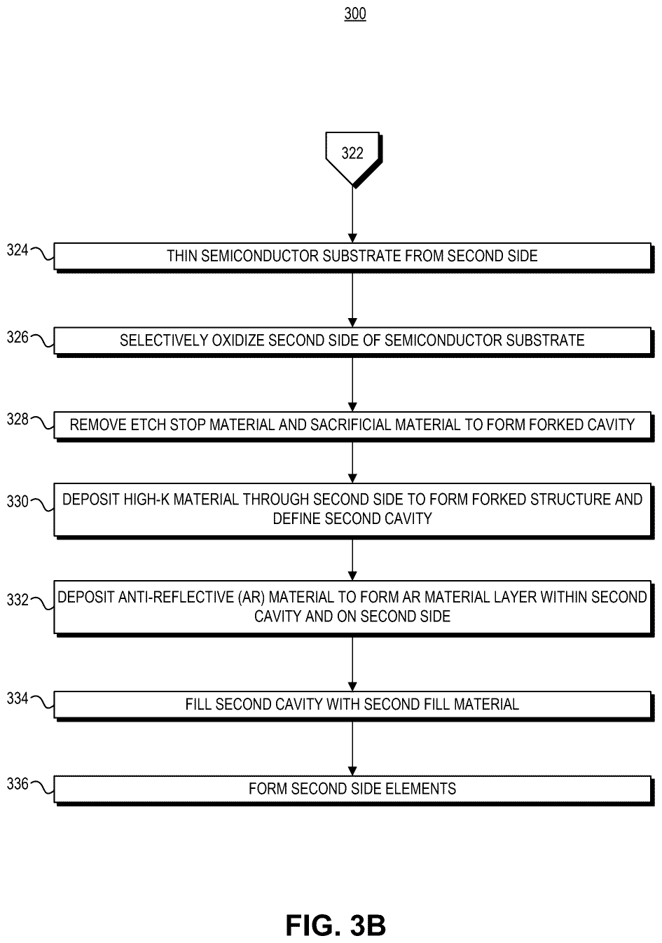

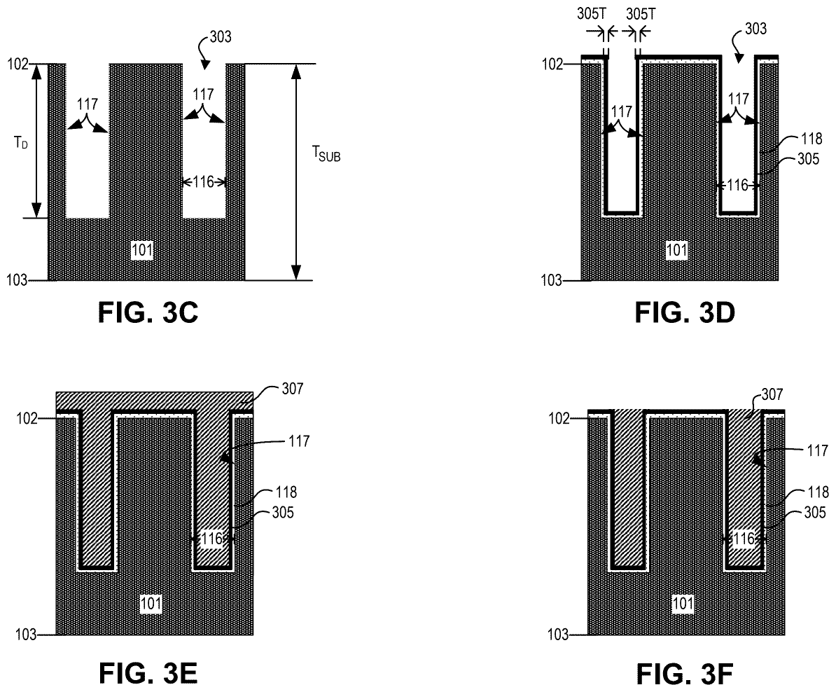

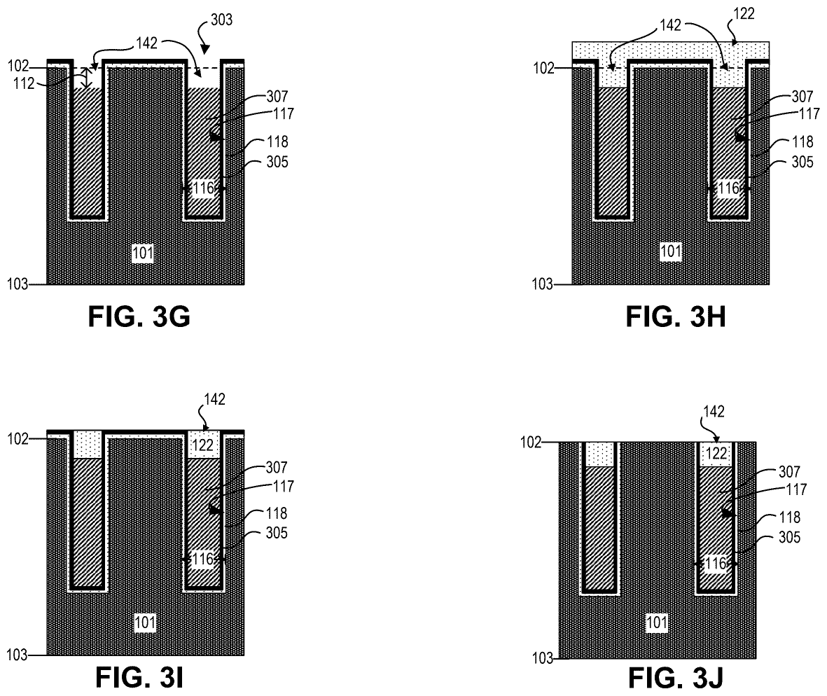

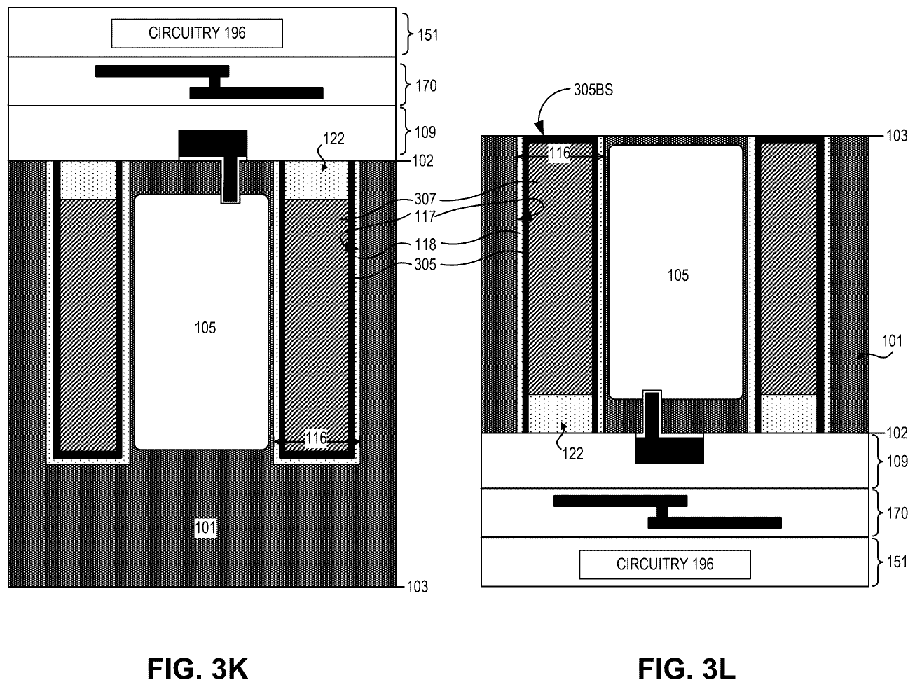

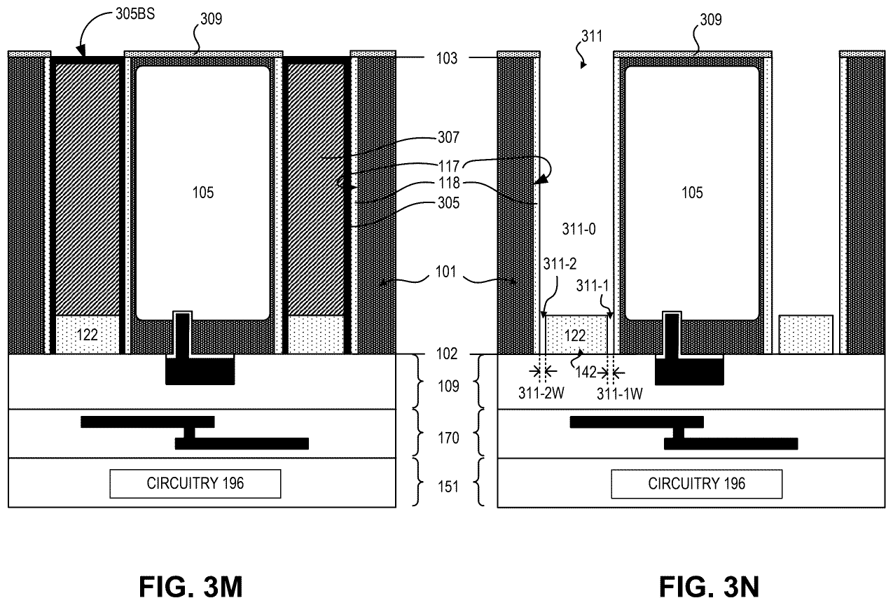

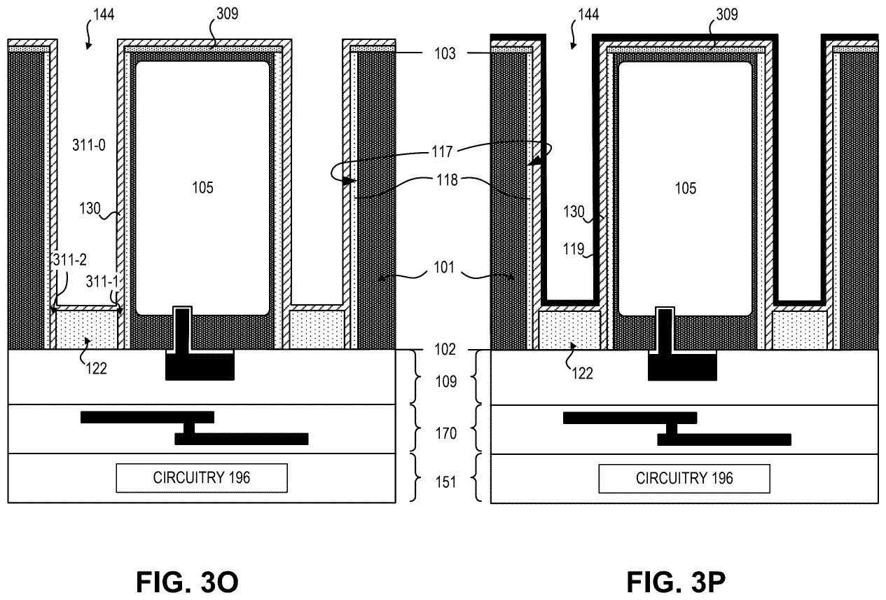

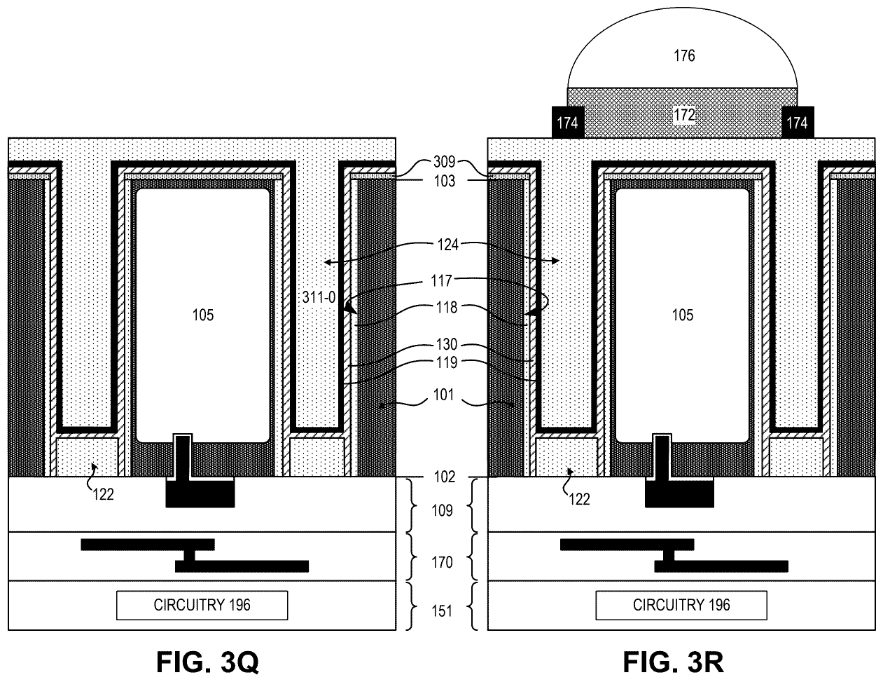

FIG. 3A-3R illustrate a method 300 for fabricating an image sensor with a forked deep trench isolation structure, in accordance with an embodiment of the disclosure. More specifically, FIG. 3A-3B illustrate method 300 for fabricating an image sensor with a forked DTI structure and FIG. 3C-3R illustrate example cross-sectional views representative of specific process blocks included in method 300. It is appreciated that method 300 is an example process for fabricating image sensor 100 illustrated in FIG. 1A-1D, forked DTI structure 115 illustrated in FIGS. 1A-1D, and modified forked DTI structure 115-V illustrated in FIG. 2, in accordance with an embodiment of the disclosure. The order in which some or all of the process blocks appear in method 300, which includes blocks 302, 304, 306, 308, 310, 312, 314, 316, 318, 320, 324, 326, 328, 330, 332, 334, and 336 should not be deemed limiting. Rather, one of ordinary skill in the art having the benefit of the present disclosure will understand that some of the process blocks may be executed in a variety of orders not illustrated, or even in parallel. Although method 300 is described in connection with forming an image sensor, it is appreciated that the forked DTI structure may also be included in other semiconductor devices.

Block 302 shows etching a semiconductor substrate (e.g., first semiconductor substrate 101 illustrated in FIG. 1A-1D) to form or define a trench in the semiconductor substrate. FIG. 3C illustrates an example schematic for process block 302 and shows trench 116 formed by etching into first semiconductor substrate 101 through first side 102. It is appreciated that the trench includes an opening 303 extending from first side 102 of first semiconductor substrate 101. The trench 116 may be formed, for example, using a patterned photoresist layer disposed over first side 102. The patterned photoresist layer may have openings or apertures defining where first semiconductor substrate 101 is etched (e.g., via ion beam sputtering). It is appreciated that the depth of trench 116 is dependent on a thickness of first semiconductor substrate 101. In some embodiments, a thickness or depth T_{D} of trench 116 is from 3.0 μm to 4.5 μm. As illustrated, the depth of trench 116 initially does not extend entirely through first semiconductor substrate 101. That is, thickness or depth T_{D} of trench 116 is less than a substrate thickness T_{SUB} of first semiconductor substrate 101, wherein the substrate thickness T_{SUB} of first semiconductor substrate 101 in FIG. 3C may be of hundreds of microns (e.g., 400-600 μm).

Block 304 illustrates conformally coating the trench formed in the semiconductor substrate with a liner material to form a liner material layer protecting the semiconductor substrate in subsequent processes. FIG. 3D illustrates an example schematic for process block 304 and shows conformally coating trench 116 formed in first semiconductor substrate 101 with liner material 118. As illustrated, liner material 118 coats sidewalls 117 of trench 116. In some embodiments, liner material 118 may be formed through thermal oxidation or deposition (e.g., chemical or physical vapor deposition). In some embodiments, liner material 118 has a thickness from 1.5 nm to 2.0 nm. In the same or other embodiments, liner material 118 protects the underlying first semiconductor substrate 101 from physical and chemical damage.

Block 306 shows conformally coating the liner material with an etch stop material. FIG. 3D also illustrates an example schematic for process block 306 and shows etch stop material 305 conformally coating liner material 118. As illustrated, etch stop material 305 extends into trench 116 such that liner material 118 is disposed between first semiconductor substrate 101 and etch stop material 305. Etch stop material 305 provides etch selectivity to a subsequently deposited sacrificial material or otherwise enables removal of the sacrificial material filling trench 116 without using a photomask (e.g., removal of polycrystalline silicon associated with block 330). In some embodiments, etch stop material 305 includes silicon nitride or silicon oxynitride. In some embodiments, etch stop material 305 may be deposited using physical or chemical vapor deposition. In embodiments, a layer thickness 305T (e.g., from 4 nm to 6 nm) of etch stop material 305 may define first width 131 of first prong 130-1 and second width 132 of second prong 130-2 illustrated in FIG. 1D and FIG. 2.

Block 308 illustrates filling the trench with a sacrificial material. FIG. 3E illustrates an example schematic for process block 308 and shows sacrificial material 307 deposited into trench 116 to fill trench 116. In some embodiments, etch stop material 305 is disposed between sacrificial material 307 and liner material 118. In some embodiments, sacrificial material 307 completely fills trench 116 and further extends over first side 102 of first semiconductor substrate 101. In some embodiments, sacrificial material 307 includes polycrystalline silicon. In one embodiment, sacrificial material 307 is deposited using chemical vapor deposition.

Block 310 shows removing excess sacrificial material proximate to a first side of the semiconductor substrate. FIG. 3F illustrates an example schematic for process block 310 and shows sacrificial material 307 etched to remove portions extending outside of trench 116. In some embodiments, first side 102 of first semiconductor substrate 101 is planarized to remove excess portions of sacrificial material 307 until sacrificial material 307 is only disposed within trench 116. In one embodiment, chemical mechanical planarization is used to planarize first side 102 of first semiconductor substrate 101 and remove excess portions of sacrificial material 307.

Block 312 illustrates partially etching the sacrificial material to form a first cavity within the trench. FIG. 3G illustrates an example schematic for process block 312 and shows partially etching sacrificial material 307 through opening 303 of trench 116 to remove a portion of sacrificial material 307 from trench 116 to form first cavity 142 extending a depth 112 into first semiconductor substrate 101 from first side 102. In some embodiments, a depth (e.g., depth 112) first cavity 142 extends into first semiconductor substrate 101 is from 30 nm to 70 nm. Advantageously, no photomask is necessary to form first cavity 142 as etch stop material 305 protects liner material 118 and first side 102 of first semiconductor substrate 101 due to etch selectivity between etch stop material 305 and sacrificial material 307. In some embodiments, sacrificial material 307 is partially etched using reactive ion etching.

Block 314 shows filling the first cavity with a first fill material. FIG. 3H illustrates an example schematic for process block 314 and shows filling first cavity 142 with first fill material 122. In the illustrated embodiment, first fill material 122 completely fills first cavity 142 and further extends outside of trench 116 over first side 102 of first semiconductor substrate 101 (e.g., deposited on the surface of first side 102 of first semiconductor substrate 101). In some embodiments, first fill material 122 is a dielectric or insulating material and includes silicon dioxide or other metal oxide material. In some embodiments, first fill material 122 may be formed using chemical or physical vapor deposition.

Block 316 illustrates removing excess first fill material proximate to the first side of the semiconductor substrate. FIG. 3I illustrates an example schematic for process block 316 and shows first fill material 122 etched to remove portions extending outside of trench 116. In some embodiments, first side 102 of first semiconductor substrate 101 is planarized to remove excess portions of first fill material 122 until first fill material 122 is only disposed within trench 116. In one embodiment, chemical mechanical planarization is used to planarize first side 102 of first semiconductor substrate 101 and remove excess portions of first fill material 122.

Block 318 shows a blanket etch back to remove the liner material and etch stop material coating the first side of the semiconductor substrate (e.g., remove the liner material and etch stop material deposited on the surface of the first side of the semiconductor substrate). FIG. 3J illustrates an example schematic for process block 318 and shows first side 102 of first semiconductor substrate 101 exposed by performing a blanket etch to remove portions of liner material 118 and etch stop material 305. It is appreciated that first side 102 of first semiconductor substrate 101 is exposed to allow for elements (e.g., photodiode, floating diffusion, transfer gate, source/drains and gate electrode of pixel transistor, ground contact, etc.) to be formed therein or thereon. In one embodiment, a blanket etch to expose first side 102 is done using plasma etching.

Block 320 illustrates forming first side elements (e.g., front side components) and bonding a second semiconductor substrate to the semiconductor substrate. FIG. 3K illustrates an example schematic for process block 320 and shows forming first side elements (e.g., photodiode 105, transfer transistor, other transistors, floating diffusion, metals, interlayer dielectric 109, metallization layer 170 and the like) and bonding second semiconductor substrate 151 to first semiconductor substrate 101. It is appreciated that during the formation of first side elements, one or more high-temperature processes (e.g., at temperatures from 750° C. to 1100° C.) may be applied or otherwise utilized to cure defects (e.g., remove dangling bonds at interfaces between different materials or components). It is appreciated that the high-temperature processes are viable since the forked structure of the forked DTI structure (e.g., forked structure 130 illustrated in FIG. 1C-1D) that includes a high-K material that is not yet formed. The high-K material provides passivation of surface detects or charges but is not compatible with high-temperature processes since high-temperature processes (e.g., greater than 500° C.) may damage the fixed negative charges of the high-k material that provide a passivation effect.

Block 322 is an off-page reference showing block 320 on FIG. 3A continues to block 324 on FIG. 3B.

Block 324 illustrates thinning the semiconductor substrate from the second side until reaching the etch stop material. FIG. 3L illustrates an example schematic for process block 324 and shows thinning first semiconductor substrate 101 from second side 103 until reaching etch stop material 305. As illustrated, first semiconductor substrate 101 is thinned until a planar surface 305BS of etch stop material 305 is exposed that is proximate to or parallel with second side 103 of first semiconductor substrate 101. In some embodiments, thinning of first semiconductor substrate 101 is achieved by mechanical grinding and polishing (e.g., chemical mechanical polishing) with the second semiconductor substrate 151 providing mechanical support.

Block 326 shows selectively oxidizing the second side of the semiconductor substrate. FIG. 3M illustrates an example schematic for process block 326 and shows performing a thermal oxidation process to oxidize exposed portions of second side 103 of first semiconductor substrate 101 to form thermal oxide 309 (e.g., SiOₓ). It is appreciated that in some embodiments, etch stop material 305 is not reactive to the thermal oxidation process and thus thermal oxide 309 does not extend over etch stop material 305. In some embodiments, thermal oxide 309 may have a thickness of ranging from approximately between 1 nm to approximately 2 nm and provides etch selectivity relative to sacrificial material 307.

Block 328 illustrates removing the etch stop material and the sacrificial material to form a forked cavity. FIG. 3N illustrates an example schematic for process block 328 and shows removing etch stop material 305 and sacrificial material 307 with etch selective processes to form forked cavity 311. In some embodiments, etch stop material 305 may be removed with a wet etch process (e.g., a SiN wet strip process that includes exposing etch stop material 305 to hot phosphoric acid) that selectively removes etch stop material 305 without significantly etching thermal oxide 309 and liner material 118. For example, hot phosphoric acid may have a high selectivity (e.g., etch rate of etch stop material 307 relative to etch rate of thermal oxide greater than 10:1, greater than 50:1, greater than 100:1, or greater than 1000:1) between etch stop material 305 and thermal oxide 309 and between etch stop material 305 and liner material 118. In some embodiments, sacrificial material 307 is also etched and removed using a wet etch process with high selectivity. For example, tetramethylammonium hydroxide may be used as a wet etch with high selectivity (e.g., etch rate of sacrificial material 307 relative to etch rate of thermal oxide greater than 10:1, greater than 50:1, greater than 100:1, or greater than 1000:1) between sacrificial material 307 and thermal oxide 309 and between sacrificial material 307 and liner material 118. Advantageously, no photomask is needed to remove etch stop material 305 and sacrificial material 307, which mitigates processing alignment and/or overlay challenges.

As illustrated, forked cavity 311 is disposed within trench 116 in first semiconductor substrate 101 having first side 102 and second side 103 opposite first side 102. Forked cavity 311 includes a body recess 311-0, a first prong recess 311-1, and a second prong recess 311-2. In some embodiments, first prong recess 311-1, and second prong recess 311-2 of forked cavity 311 may define openings to or otherwise expose portion of interlayer dielectric 109. In the illustrated embodiment, first fill material 122 is disposed between the first prong recess 311-1 and the second prong recess 311-2. In the same or other embodiments, first prong recess 311-1 and second prong recess 311-2 extend from body recess 311-0 toward first side 102 of first semiconductor substrate 101. In the same or other embodiment, body recess 311-0 extends from second side 103 of first semiconductor substrate 101 towards first side 102 of first semiconductor substrate 101. In one embodiment, a first recess width 311-1W of first prong recess 311-1 defines first width 131 of first prong 130-1 and a second recess width 311-2W of second prong recess 311-2 defines second width 132 of second prong 130-2.

Block 330 shows depositing a high-K material through second side of the semiconductor substrate into the forked cavity to form a forked structure and define a second cavity. FIG. 3O illustrates an example schematic for process block 330 and shows depositing a high-K material through second side 103 of first semiconductor substrate 101 into forked cavity 311 to form a forked structure 130. In some embodiments, the high-K material conformally coats sidewalls and surfaces of body recess 311-0 and further extends into first prong recess 311-1 and second prong recess 311-1 such that forked structure 130 includes a first prong, a second prong, and an intermediary portion (see, e.g., FIG. 1D) with the first prong and the second prong extending from the intermediary portion towards first side 102 of first semiconductor substrate 101. It is appreciated that dimensionality and relative of arrangement of components of forked structure 130 are described in relation to FIGS. 1C-1D and are not reiterated here for sake of brevity.

It is appreciated that by coating sidewalls and surfaces of forked cavity 311, forked structure 130 forms second cavity 144. Second cavity 144 extends into first semiconductor substrate 101 from second side 103. In some embodiments, the high-k material also coats thermal oxide 309 (e.g., the high-k material is disposed proximate to second side 103 of first semiconductor substrate 101 on thermal oxide 309). In some embodiments, an atomic layer deposition process may be used to deposit the high-K material that conformally coats sidewalls and surfaces defining forked cavity 311 to form forked structure 130. In some embodiments, individual prongs of forked structure 130 are from 6.5 nm to 8.0 nm thick. In some embodiments, first and/or second prongs of forked structure 130 may be in direct contact with interlayer dielectric 109. Advantageously, a photomask is not necessary when depositing the high-material to form forked structure 130.

As illustrated, forked structure 130 extends from first side 102 to second side 103 of first semiconductor substrate 101 such that the passivation effect provided by the fixed negative charges of the high-K material covers a length of the liner material 118 while maintaining compatibility with high-thermal processes to anneal out defects and remove dangling bonds. Forked structure 130 extends from first side 102 to second side 103 of first semiconductor substrate 101 as illustrated and forked structure 130 further defines second cavity 144.

Block 332 illustrates depositing an anti-reflective (AR) coating material to form an AR material layer within the second cavity and on the second side of the first semiconductor substrate. FIG. 3P illustrates an example schematic for process block 332 and shows AR material layer 119 formed by depositing an AR material that conformally coats second cavity 144 and extends across second side 103 of first semiconductor substrate 101. In some embodiments, atomic layer deposition or chemical vapor deposition is used to form AR material layer 119.

Block 334 shows filling the second cavity with a second fill material. FIG. 3Q illustrates an example schematic for process block 334 and shows depositing second fill material 124 into body recess 311-0 such that the intermediary portion of the forked structure 130 is disposed between the first fill material 122 and the second fill material 124. In some embodiments, second fill material 124 may be deposited using chemical of physical vapor deposition. Advantageously, the body recess 311-0 of the forked cavity may be filled without using a photomask, which improves yield relative to using a photomask with apertures aligned with body recess 311-0.

Block 336 illustrates forming second side elements (e.g., back side components). FIG. 3R illustrates an example schematic for process block 336 and shows forming second side elements (e.g., color filters 172, metal grid 174, microlens 176, and the like). Metal grid 174 may define an aperture optically aligned with photodiode 105. Color filter 172 may be disposed within the aperture defined by metal grid 174. Microlens 176 may be formed or otherwise disposed on the color filter 172 to direct incident light to photodiode 105.

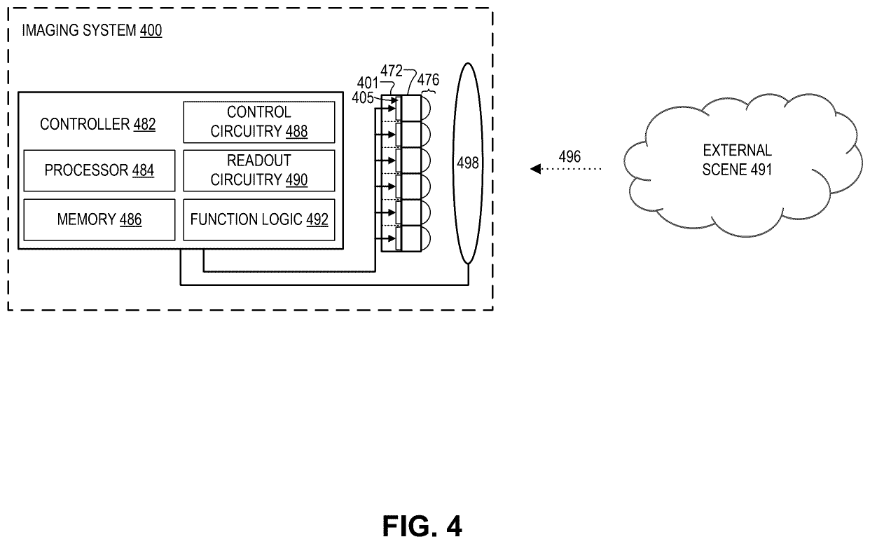

FIG. 4 is a functional block diagram of an imaging system 400 with a forked deep trench isolation structure (e.g., forked DTI structure 115 and 115-V illustrated in FIG. 1A-2) may be fabricated using the method 300 illustrated in FIG. 3A-3R, in accordance with an embodiment of the disclosure. For example, semiconductor substrate 401 includes a forked DTI structure to mitigate crosstalk between adjacent pixels. Imaging system 400 includes the photodiodes 405 configured to generate image charge in response to incident light 496 for imaging external scene 491, objective lens(es) 498 with adjustable optical power to focus on one or more points of interest within external scene 491, and controller 482 to control, inter alia, operation of imaging system 400. Imaging system 400 is a simplified schematic showing semiconductor substrate 401 with a plurality of photodiodes 405 disposed within respective portions of semiconductor substrate 401, a plurality of color filters 472, and a plurality of microlenses 476. Controller 482 includes one or more processors 484, memory 486, control circuitry 488, readout circuitry 490, and function logic 492.

Controller 482 includes logic and/or circuitry to control the operation (e.g., during pre-, post-, and in situ phases of image and/or video acquisition) of the various components of imaging system 400. Controller 482 can be implemented as hardware logic (e.g., application specific integrated circuits, field programmable gate arrays, system-on-chip, etc.), software/firmware logic executed on a general-purpose microcontroller or microprocessor, or a combination of both hardware and software/firmware logic. In one embodiment, controller 482 includes processor 484 coupled to memory 486 that stores instructions for execution by controller 482, processor 484, one or more other components of imaging system 400, or more generally imaging system 400. The instructions, when executed, can cause imaging system 400 to perform operations associated with the various functional modules, logic blocks, or circuitry of imaging system 400 including any one of, or a combination of, control circuitry 488, readout circuitry 490, function logic 492, components included in or on semiconductor substrate 401 such as plurality of photodiodes 405, objective lens 498, and/or any other element of imaging system 400 (illustrated or otherwise). Memory 486 is a non-transitory computer-readable medium that can include, without limitation, a volatile (e.g., RAM) or non-volatile (e.g., ROM) storage system readable by controller 482. It is further appreciated that controller 482 can be a monolithic integrated circuit, one or more discrete interconnected electrical components, or a combination thereof, which may be formed on one or more substrates that are coupled together. Additionally, in some embodiments one or more electrical components can be coupled together to collectively function as controller 482 for orchestrating operation of the imaging system 400.

Control circuitry 488 can control operational characteristics of the array formed by plurality of photodiodes 405 (e.g., exposure duration, when to capture digital images or videos, and the like). Readout circuitry 490 reads or otherwise samples the analog signal from individual photodiodes (e.g., read out electrical signals based on image charge generated by each of plurality of photodiodes 405 in response to incident light 496 to generate image signals for capturing an image frame representative of external scene 491, and the like) and can include amplification circuitry, analog-to-digital (ADC) circuitry, image buffers, or otherwise. In the illustrated embodiment, readout circuitry 490 is included in controller 482, but in other embodiments readout circuitry 490 can be separate from controller 482. Function logic 492 is coupled to readout circuitry 490 to receive image data to de-mosaic the image data and generate one or more image frames. In some embodiments, the electrical signals and/or image data can be manipulated or otherwise processed by function logic 492 (e.g., apply post image effects such as crop, rotate, remove red eye, adjust brightness, adjust contrast, or otherwise).

It is appreciated that embodiments of the disclosure illustrated in FIG. 1A-4 may be fabricated using conventional semiconductor device processing and microfabrication techniques known by one of ordinary skill in the art, which may include, but is not limited to, photolithography, ion implantation, chemical vapor deposition, physical vapor deposition, thermal evaporation, sputter deposition, reactive-ion etching, plasma etching, wafer bonding, chemical mechanical planarization, and the like. It is appreciated that the described techniques are merely demonstrative and not exhaustive and that other techniques may be utilized to fabricate one or more components of various embodiments of the disclosure.

The above description of illustrated examples of the invention, including what is described in the Abstract, is not intended to be exhaustive or to limit the invention to the precise forms disclosed. While specific examples of the invention are described herein for illustrative purposes, various modifications are possible within the scope of the invention, as those skilled in the relevant art will recognize.

These modifications can be made to the invention in light of the above detailed description. The terms used in the following claims should not be construed to limit the invention to the specific examples disclosed in the specification. Rather, the scope of the invention is to be determined entirely by the following claims, which are to be construed in accordance with established doctrines of claim interpretation.

What is claimed is:

1. An image sensor, comprising:
a photodiode disposed within a semiconductor substrate having a first side and a second side opposite the first side; and
a forked deep trench isolation (DTI) structure configured to isolate the photodiode from adjacent photodiodes included in the image sensor, wherein the forked DTI structure includes:
a trench disposed within the semiconductor substrate between the first side and the second side;
a forked structure disposed within the trench, the forked structure including a first prong, a second prong, and an intermediary portion, wherein the first prong and the second prong extend from the intermediary portion towards the first side of the semiconductor substrate to form a first cavity within the trench, and wherein the first cavity is disposed between the first prong and the second prong; and
a second cavity disposed within the trench, wherein the intermediary portion is disposed between the first cavity and the second cavity, and wherein the first cavity includes a first fill material and the second cavity includes a second fill material.

2. The image sensor of claim 1, wherein the intermediary portion laterally extends continuously from the first prong to the second prong such that the first fill material is separated from the second fill material.

3. The image sensor of claim 1, wherein the forked DTI structure further includes a liner material disposed between sidewalls of the trench and the first fill material, wherein the first prong is disposed between the liner material and the first fill material, and wherein the second prong is disposed between the liner material and the first fill material.

4. The image sensor of claim 1, wherein the first cavity extends a first depth into the semiconductor substrate from the first side of the semiconductor substrate, wherein the second cavity extends a second depth into the semiconductor substrate from the second side of the semiconductor substrate, and wherein the first depth is less than the second depth.

5. The image sensor of claim 4, wherein the first prong and the second prong each extend the first depth into the semiconductor substrate.

6. The image sensor of claim 1, wherein the forked DTI structure further includes a third prong and a fourth prong extending from the intermediary portion towards the second side of the semiconductor substrate in a direction perpendicular to the second side of the semiconductor substrate to form the second cavity within the trench, and wherein the second cavity is disposed between the third prong and the fourth prong.

7. The image sensor of claim 6, wherein the forked DTI structure further includes an anti-reflective (AR) material layer disposed between the second fill material and the third prong, and wherein the AR material layer is further disposed between the second fill material and the fourth prong.

8. The image sensor of claim 6, wherein the third prong is aligned with the first prong in the direction perpendicular to the second side of the semiconductor substrate, and wherein the fourth prong is aligned with the second prong in the direction perpendicular to the second side of the semiconductor substrate.

9. The image sensor of claim 6, wherein a width of the first prong proximate to the first side of the semiconductor substrate along a direction parallel to the first side of the semiconductor substrate is less than a width of the third prong proximate to the second side of the semiconductor substrate along the direction parallel to the first side of the semiconductor substrate.

10. The image sensor of claim 6, wherein the intermediary portion is disposed closer to the first side of the semiconductor substrate relative to the second side of the semiconductor substrate.

11. The image sensor of claim 6, wherein the forked DTI structure extends through a full depth of the semiconductor substrate, wherein the first prong, the third prong, and the intermediary portion collectively extend the full depth of the semiconductor substrate, and wherein the second prong, the fourth prong, and the intermediary portion collectively extend the full depth of the semiconductor substrate.

12. The image sensor of claim 11, wherein the third prong is longer than the first prong along a direction perpendicular to the first side of the semiconductor substrate, and wherein the fourth prong is longer than the second prong.

13. The image sensor of claim 6, wherein the forked DTI structure further includes a liner material disposed between sidewalls of the trench and the second fill material, wherein the third prong is disposed between the liner material and the second fill material, and wherein the fourth prong is disposed between the liner material and the second fill material.

14. The image sensor of claim 13, further comprising an extended isolation structure disposed within the semiconductor substrate proximate to the first side, wherein the extended isolation structure extends from the first side of the semiconductor substrate towards the liner material disposed proximate to the third prong, and wherein a first thickness of the liner material proximate to the third prong is less than a second thickness of the extended isolation structure in a direction parallel to the first side of the semiconductor substrate.

15. The image sensor of claim 1, further comprising a transfer gate including a vertical portion extending into the semiconductor substrate from the first side, and wherein the vertical portion of the transfer gate is disposed closer to the second side of the semiconductor substrate than the intermediary portion of the forked structure.

16. The image sensor of claim 1, wherein the first prong, the second prong, and the intermediary portion form a monolithic structure including a high-K material.

17. A method for forming a forked deep trench (DTI) isolation structure for an image sensor, the method comprising:
forming a forked cavity within a semiconductor substrate having a first side and a second side opposite the first side, wherein the forked cavity includes a body recess, a first prong recess, and a second prong recess, wherein a first fill material is disposed between the first prong recess and the second prong recess, wherein the first prong recess and the second prong recess extend from the body recess toward the first side of the semiconductor substrate, and wherein the body recess extends from the second side of the semiconductor substrate;
depositing a high-k material through the second side of the semiconductor substrate to form a forked structure, wherein the high-K material conformally coats the body recess and further extends into the first prong recess and the second prong recess such that the forked structure includes a first prong, a second prong, and an intermediary portion, wherein the first prong and the second prong extend from the intermediary portion towards the first side of the semiconductor substrate; and
depositing a second fill material into the body recess such that the intermediary portion of the forked structure is disposed between the first fill material and the second fill material.

18. The method of claim 17, wherein forming the forked cavity includes:
conformally coating a trench formed in the semiconductor substrate with a liner material, wherein the trench includes an opening extending from the first side of the semiconductor substrate;
conformally coating the liner material with an etch stop material, wherein the etch stop material extends into the trench such that the liner material is disposed between the semiconductor substrate and the etch stop material;
filling the trench with a sacrificial material, wherein the etch stop material is disposed between the sacrificial material and the liner material;
partially etching the sacrificial material through the opening to form a first cavity within the trench extending from the first side of the semiconductor substrate;
filling the first cavity with the first fill material;
thinning the semiconductor substrate from the second side until reaching the etch stop material;
removing the etch stop material and the sacrificial material to form the forked cavity.

19. The method of claim 18, wherein the etch stop material and the sacrificial material are removed with a respective wet etch.

20. The method of claim 18, wherein the depositing the high-K material through the second side of the semiconductor substrate to form the forked structure causes the forked structure to further include a third prong and a fourth prong extending from the intermediary portion towards the second side of the semiconductor substrate, wherein the second fill material is different from the high-k material, and wherein the second fill material is disposed between the third prong and the fourth prong.
